(19) United States
(12) Patent Application Publication
(10) Pub. No.: US 2026/0130162 A1
(43) Pub. Date: May 7, 2026

(54) SUBSTRATE TREATING METHOD AND SUBSTRATE TREATING APPARATUS

(71) Applicants: PSK Inc., Gyeonggi-do (KR); RTM Inc., Seoul (KR)

(72) Inventors: Tae Kyung HA, Gyeonggi-do (KR); Jin Kyu KIM, Gyeonggi-do (KR); Jin Woo PARK, Seoul (KR); Gyu Il HWANG, Seoul (KR)

(21) Appl. No.: 19/382,750

(22) Filed: Nov. 7, 2025

(30) Foreign Application Priority Data
Nov. 7, 2024 (KR) 10-2024-0157152

(51) Int. Cl. H01L 21/67; H01L 21/687

(52) U.S. Cl. CPC H10P 72/06; H10P 72/0454; H10P 72/0464; H10P 72/7602; H10P 72/0466

(57) ABSTRACT

An exemplary embodiment of the present invention provides a substrate treating method and a substrate treating apparatus that are capable of preventing contamination of a subsequent substrate. According to the exemplary embodiment, when the pressure monitoring operation of the transfer chamber, the method may include acquiring a graph representing the pressure change in the transfer chamber over time, and determining whether there is a pressure abnormality inside the transfer chamber based on a shape of the graph.

### CROSS-REFERENCE TO RELATED APPLICATION

This application claims priority to and the benefit of Korean Patent Application No. 10-2024-0157152 filed in the Korean Intellectual Property Office on Nov. 7, 2024, the entire contents of which are incorporated herein by reference.

### TECHNICAL FIELD

The present invention relates to a method of treating a substrate and an apparatus for treating a substrate, and more specifically, to a substrate treating method and a substrate treating apparatus that are capable of preventing contamination of a subsequent substrate.

### BACKGROUND ART

Semiconductors are generally manufactured by sequentially performing a series of unit processes for film formation, pattern formation, metal wiring formation, and the like. The unit processes are generally performed inside a process chamber, and a substrate treating apparatus includes a load port, an index module, a load lock chamber, and a transfer chamber to provide a substrate into the process chamber. The load port supports a carrier in which the substrate is accommodated, and the index module includes a transfer robot that transfers the substrate between the load port and the load lock chamber. In the load lock chamber, the substrate that has been treated temporarily waits before being transferred to the load port or the substrate to be provided for a substrate treatment temporarily waits before being transferred to the process chamber, and the transfer chamber transfers the substrate between the load lock chamber and the process chamber.

In general, when a substrate is transferred between the process chamber and the transfer chamber, the internal pressure of the process chamber is set lower than the internal pressure of the transfer chamber, and then the door of the process chamber is opened to transfer the substrate. By doing so, it is possible to prevent diffusion of impurities generated during the process into the transfer chamber.

However, when the doors of a plurality of process chambers are opened simultaneously or continuously, there is a possibility that the pressure inside the transfer chamber is lower than the pressure inside the process chamber. For this reason, impurities inside the process chamber may diffuse into the transfer chamber, and when the transfer chamber is contaminated, the risk of contamination of the substrate to be subsequently treated increases.

Accordingly, it is possible to consider installing a pressure sensor in the transfer chamber and the process chamber and comparing the pressures in real time to check in real time whether the pressure inside the transfer chamber is lower than the pressure inside the process chamber. However, since the volume of the process chamber is smaller than that of the transfer chamber and has high pressure variability, it is difficult to determine whether the transfer chamber is contaminated by comparing the pressure between the transfer chamber and the process chamber only with the measured value of the pressure sensor installed in the process chamber. This inaccurate determination makes it unclear from when the substrate has been contaminated and may eventually lead to a problem of having to dispose all treated substrates.

### SUMMARY OF THE INVENTION

The present invention has been made in an effort to provide a substrate treating apparatus and a substrate treating method capable of improving substrate treatment efficiency.

The present invention has also been made in an effort to provide a substrate treating method and a substrate treating apparatus capable of detecting contamination of a transfer chamber and a substrate in real time.

The present invention has also been made in an effort to provide a substrate treating method and a substrate treating apparatus capable of preventing the disposal of subsequent substrates even when a transfer chamber is contaminated.

The object of the present invention is not limited thereto, and other objects not mentioned may be clearly understood by those skilled in the art from the following description.

An exemplary embodiment of the present invention provides a method of treating a substrate, the method including: a substrate loading operation of loading a substrate into a process chamber selected from a plurality of process chambers with a transfer robot placed in a transfer chamber in a substrate treating apparatus including the transfer chamber and the plurality of process chambers placed around the transfer chamber; a treating operation of treating the substrate in the process chamber into which the substrate is loaded; after the treating operation, an unloading operation of opening a door of the transfer chamber, and unloading the substrate from the process chamber by using the transfer robot; and a pressure monitoring operation of monitoring a pressure change inside the transfer chamber, in which a pressure in the process chamber is provided at a pressure lower than a pressure in the transfer chamber in the unloading operation, and the pressure monitoring operation includes monitoring whether there is a pressure abnormality inside the transfer chamber.

According to the exemplary embodiment, the pressure monitoring operation may include monitoring the pressure change in the transfer chamber in the unloading operation.

According to the exemplary embodiment, the transfer robot may include a handle that grips a substrate, the unloading operation includes a gripping operation of gripping the substrate in the process chamber with the handle, and the pressure monitoring operation includes monitoring the pressure change inside the transfer chamber until the gripping operation.

According to the exemplary embodiment, the pressure monitoring operation may include acquiring a first graph representing the pressure change in the transfer chamber over time, and determining whether there is a pressure abnormality inside the transfer chamber based on a shape of the first graph.

According to the exemplary embodiment, when the shape of the first graph is convex downward, it may be determined that the pressure inside the transfer chamber is in a normal state, and when the shape of the first graph is convex upward, it may be determined that the pressure inside the transfer chamber is in an abnormal state.

According to the exemplary embodiment, when it is determined that the pressure inside the transfer chamber is in the abnormal state, an alarm may be generated.

According to the exemplary embodiment, the pressure monitoring operation may include comparing the acquired first graph with a database to determine whether there is a pressure abnormality inside the transfer chamber, and the database may include: a plurality of first graphs acquired while the pressure monitoring operation has been performed multiple times in the past; and a second graph representing a pressure change inside the process chamber acquired while the pressure monitoring operation has been performed multiple times in the past.

According to the exemplary embodiment, the database may include: an initial pressure value inside the transfer chamber in the unloading operation; an average value of an internal pressure of the transfer chamber in a first section; an average value of the internal pressure of the transfer chamber in a second section; an average value of an internal pressure of the process chamber in the first section; an average value of an internal pressure of the process chamber in the second section; the first section may be a set time interval before the door is opened in the unloading operation, and the second section may be a set time interval after the door is opened in the unloading operation.

According to the exemplary embodiment, the database may be learned using an artificial intelligence learning model, and it may be determined whether there is the pressure abnormality inside the transfer chamber from the measured pressure change inside the transfer chamber.

In addition, an apparatus for treating a substrate, the apparatus comprising: a transfer chamber including a transfer robot that transfers a substrate; a plurality of process chambers provided adjacent to the transfer chamber; and a controller, wherein the transfer chamber has a first pressure sensor that measures a pressure inside the transfer chamber, each of the plurality of process chambers may have an exhaust unit that exhausts an inside of the process chamber, each of the process chambers may be provided to have an open state and a closed state by opening and closing a door, the open state may be a state in which the door is opened so that the transfer chamber and the process chamber communicate with each other, the closed state may be a state in which the door is closed so that the transfer chamber and the process chamber are blocked from each other, in the closed state, an internal pressure of the transfer chamber may be provided to have a first pressure, and an internal pressure of the process chamber may be provided to have a second pressure lower than the first pressure, the controller controls the transfer chamber and the process chamber to perform: a treating operation of treating the substrate in the process chamber in which the substrate may be loaded; an unloading operation of unloading the treated substrate from the process chamber using the transfer robot; and a pressure monitoring operation of monitoring a pressure change inside the transfer chamber and determining whether there is a pressure abnormality inside the transfer chamber, and a pressure in the process chamber is provided at a pressure lower than a pressure in the transfer chamber in the unloading operation, and whether there is the pressure abnormality inside the transfer chamber is monitored in the pressure monitoring operation.

According to the exemplary embodiment, the pressure change measured by the first pressure sensor may be a pressure change in the open state.

According to the exemplary embodiment, the pressure change measured by the first pressure sensor may be a pressure change until at least one of the plurality of process chambers is switched from the closed state to the open state, and a handle of the transfer robot may enter the process chamber and grips the substrate.

According to the exemplary embodiment, the controller may generate and acquire a first graph representing the pressure measured by the first pressure sensor in the monitoring operation as a change over time, and may determine whether there is the pressure abnormality inside the transfer chamber based on a shape of the first graph.

According to the exemplary embodiment, when the shape of the first graph is convex downward, the controller may determine that the pressure inside the transfer chamber is in a normal state, and when the shape of the first graph is convex upward, the controller may determine that the pressure inside the transfer chamber is in an abnormal state.

According to the exemplary embodiment, the controller may control the transfer chamber or the process chamber to generate an alarm when it is determined that the pressure inside the transfer chamber is in the abnormal state.

According to the exemplary embodiment, each of the process chambers may have a second pressure sensor that measures a pressure inside the process chamber, the controller compares the acquired first graph with a database to determine whether there is the pressure abnormality inside the transfer chamber, the database includes: a plurality of first graphs acquired while the pressure monitoring operation has been performed multiple times in the past; and a second graph representing a pressure change inside the process chamber acquired while the pressure monitoring operation has been performed multiple times in the past.

According to the exemplary embodiment, the database may include: an initial pressure value inside the transfer chamber in the unloading operation; an average value of the internal pressure of the transfer chamber in a first section; an average value of the internal pressure of the transfer chamber in a second section; an average value of an internal pressure of the process chamber in the first section; an average value of an internal pressure of the process chamber in the second section; the first section is a set time interval before the door is opened in the unloading operation, and the second section may be a set time interval after the door is opened in the unloading operation.

According to the exemplary embodiment, the controller may learn the database using an artificial intelligence learning model, and monitors whether there is the pressure abnormality inside the transfer chamber from the measured first graph.

In addition, a method of treating a substrate, the method comprising: a substrate loading operation of loading a substrate into a process chamber selected from a plurality of process chambers with a transfer robot placed in a transfer chamber in a substrate treating apparatus including the transfer chamber and the plurality of process chambers placed around the transfer chamber; a treating operation of treating the substrate in the process chamber into which the substrate is loaded; after the treating operation, an unloading operation of opening a door of the transfer chamber, and unloading the substrate from the process chamber by using the transfer robot; and a pressure monitoring operation of monitoring a pressure change inside the transfer chamber and determining whether there is a pressure abnormality inside the transfer chamber, a pressure in the process chamber is provided at a pressure lower than a pressure in the transfer chamber in the unloading operation, and the transfer robot includes a handle that grips a substrate, the pressure monitoring operation includes: acquiring a first graph representing the pressure change in the transfer chamber over time in the unloading operation, and determining whether there is the pressure abnormality inside the transfer chamber based on a shape of the first graph, and when the shape of the first graph is convex downward, it is determined that the pressure inside the transfer chamber is in a normal state, and when the shape of the first graph is convex upward, it is determined that the pressure inside the transfer chamber is in an abnormal state, and when it is determined that the pressure inside the transfer chamber is in the abnormal state, an alarm may be generated.

According to the exemplary embodiment, the pressure monitoring operation may include learning a database using an artificial intelligence learning model, and determining whether there is the pressure abnormality inside the transfer chamber by comparing the acquired first graph and the database, and the database may include: an initial pressure value inside the transfer chamber in the unloading operation; an average value of the internal pressure of the transfer chamber in a first section; an average value of the internal pressure of the transfer chamber in a second section; an average value of an internal pressure of the process chamber in the first section; an average value of an internal pressure of the process chamber in the second section; the first section may be a set time interval before the door is opened in the unloading operation, and the second section may be a set time interval after the door is opened in the unloading operation.

According to the exemplary embodiment of the present invention, it is possible to improve substrate treatment efficiency.

According to the exemplary embodiment of the present invention, it is possible to detect contamination of a transfer chamber and a substrate in real time.

According to the exemplary embodiment of the present invention, it is possible to prevent the disposal of subsequent substrates even when a transfer chamber is contaminated.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of whats. The accompanying drawings are not considered to be drawn to scale unless explicitly stated. For clarity, the various dimensions of the drawings may have been exaggerated.

FIG. 1 is a top plan view schematically illustrating a substrate treating apparatus according to an exemplary embodiment of the present invention.

FIG. 2 is a flowchart illustrating a substrate treating method according to an exemplary embodiment of the present invention.

FIG. 3 is a diagram illustrating an example of a graph acquired in a pressure monitoring operation according to an exemplary embodiment of the present invention.

FIG. 4 is a diagram illustrating another example of a graph acquired in a pressure monitoring operation according to an exemplary embodiment of the present invention.

FIG. 5 is a flowchart illustrating a pressure monitoring operation according to another exemplary embodiment of the present invention.

FIG. 6 is a diagram illustrating an example of a state in which a plurality of graphs is acquired and stored.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as a target to be treated. However, the technical spirit of the present invention may be applied to apparatuses used for treating other types of substrates, other than wafers, as targets to be treated.

Hereinafter, an exemplary embodiment of the present invention will be described with reference to the accompanying drawings.

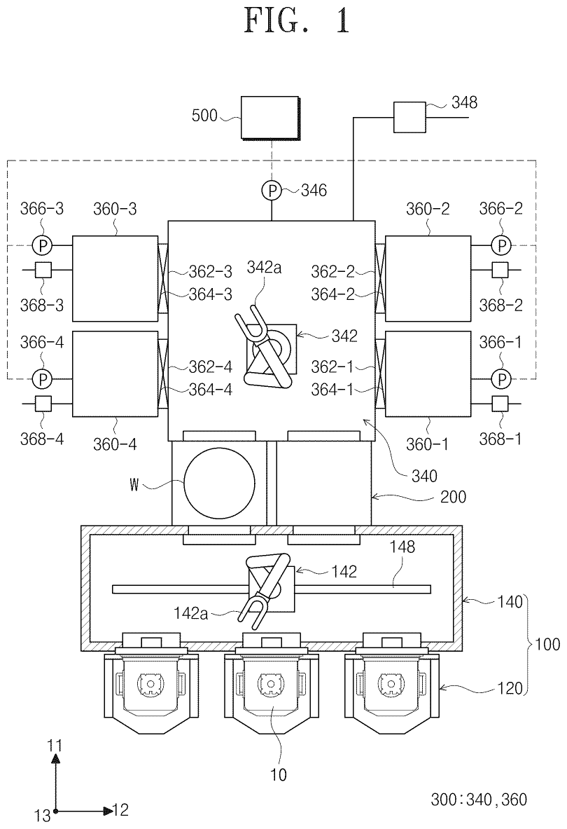

FIG. 1 is a top plan view schematically illustrating a substrate treating apparatus according to an exemplary embodiment of the present invention. Referring to FIG. 1, a substrate treating apparatus 1 includes an index module 100, a load lock chamber 200, a treating module 300, and a controller 500. The index module 100, the load lock chamber 200, and the treating module 300 are disposed along a predetermined direction. The index module 100, the load lock chamber 200, and the treating module 300 are disposed along a first direction 11.

The index module 100 transfers a substrate W from a container 10 in which the substrate W is accommodated to the treating module 300, and makes the substrate W, which has been completely processed in the treating module 300, be accommodated in the container 10. A longitudinal direction of the index module 100 is provided in a second direction 12. The index module 100 includes a load port 120 and an index frame 140. Based on the index frame 140, the load port 120 is located at a side opposite to the treating module 300. The containers 10 in which the substrates W are accommodated are placed on the load ports 120. A plurality of load ports 120 may be provided.

As the container 10, an airtight container, such as a Front Open Unified Pod (FOUP), may be used. The container 10 may be placed on the load port 120 by a transfer means (not illustrated), such as an overhead transfer, an overhead conveyor, or an automatic guided vehicle, or an operator.

The index frame 140 may have a space sealed from the outside. The space in the index frame 140 may be provided with atmospheric pressure. Selectively, the space in the index frame 140 may be provided with a pressure higher than atmospheric pressure. A fan filter unit (not illustrated) is provided at the upper end of the index frame 140. The fan filter unit forms descending airflow within the index frame 140. A door opener (not illustrated) for opening and closing a door of the container 10 may be provided in the index frame 140.

An index robot 142 is provided to the index frame 140. A guide rail 148 of which a longitudinal direction is the second direction 12 is provided within the index frame 140, and the index robot 142 may be provided to be movable on the guide rail 148. The index robot 142 includes a hand 142a on which the substrate W is placed, and the hand 142a may be provided to be movable forward and backward, rotatable in the vertical direction, and movable in the vertical direction. The plurality of hands 142a is provided while being spaced apart from each other in the vertical direction, and is capable of independently moving forward and backward.

The load lock chamber 200 is disposed adjacent to the index frame 140. The load lock chamber 200 may be disposed between the transfer chamber 340 and the index module 100. The substrate W transferred from the container 10 to the process chamber 360 may be temporarily stored in the load lock chamber 200 after being taken out of the container 10. Furthermore, the substrate W on which the process is completed in the process chamber 360 may be temporarily stored in the load lock chamber 200 while being transferred to the container 10. A plurality of load lock chambers 200 may be provided. The substrate W may be transferred between the index frame 140 and the transfer chamber 340 through each load lock chamber 200. Optionally, the substrate W may be transferred from the index frame 140 to the transfer chamber 340 through one of the load lock chambers 200, and may be transferred from the transfer chamber 340 to the index frame 140 through the other of the load lock chambers 200.

The treating module 300 includes a transfer chamber 340 and a process chamber 360. The transfer chamber 340 is disposed adjacent to the load lock chamber 200. When viewed from above, the transfer chamber 340 may be provided in a polygonal shape. A transfer robot 342 is disposed in the transfer chamber 340. The transfer robot 342 transfers the substrate W between the load lock chamber 200 and the process chamber 360. The inside of the transfer chamber 340 may be provided with vacuum pressure.

The transfer robot 342 includes a hand 342a on which the substrate W is placed, and the hand 342a may be provided to be movable forward and backward, rotatable in the vertical direction, and movable in the vertical direction. The plurality of hands 342a is provided while being spaced apart from each other in the vertical direction, and is capable of independently moving forward and backward. One of the hands 342a may support the substrate W transferred from the load lock chamber 200 to the process chamber 360, and the other of the hands 342a may support the substrate W transferred from the process chamber 360 to the load lock chamber 200.

Furthermore, the internal pressure of the transfer chamber 340 may be measured by a first pressure sensor 346. The first pressure sensor 346 is provided to be able to transmit the measured value to the controller 500. The first pressure sensor 346 may be provided as a Baratron gauge, a Pirani gauge, or a thermocouple gauge, but the present invention is not limited thereto, and the pressure sensor is sufficient as long as the pressure sensor is capable of measuring the pressure inside the transfer chamber 340.

The inside of the transfer chamber 340 is exhausted by the exhaust member 348. The exhaust member 348 is provided to depressurize the inside of the transfer chamber 340. The exhaust member 348 allows the internal pressure of the transfer chamber 340 to be formed within a specific range. In one example, the exhaust member 348 may be a pump.

The process chamber 360 performs a process of treating the substrate W. According to an example, the process chamber 360 may perform a process of forming plasma using an Inductively Coupled Plasma (ICP) method or a Conductively Coupled Plasma (CCP) method and treating the substrate W using plasma. For example, the process chamber 360 may perform a process of etching a thin film on the substrate W or a process of etching an outermost edge region (bevel) of the substrate W.

The process chamber 360 includes a door 364, a second pressure sensor 366, and an exhaust member 368.

The door 364 is provided to open and close an entrance 362 of the process chamber. In the case in which the door 364 is opened, the inner spaces of the transfer chamber 340 and the process chamber 360 are connected to each other. On the contrary, in the case in which the door 364 is closed, the inner spaces of the transfer chamber 340 and the process chamber 360 are blocked from each other. The door 364 may be operated by a driver, which is not illustrated, and the driver may be provided in a cylinder type. The door 364 may be controlled by the controller 500 to switch between the open state and the closed state.

The second pressure sensor 366 measures an internal pressure of the process chamber 360. The second pressure sensor 366 is provided to be able to transmit the measured value to the controller 500. The second pressure sensor 366 may be provided as a Baratron gauge, a Pirani gauge, or a thermocouple gauge, but the present invention is not limited thereto, and the pressure sensor is sufficient as long as the pressure sensor is capable of measuring the pressure inside the transfer chamber 360.

The exhaust member 368 exhausts the inside of the process chamber 360. The exhaust member 368 may adjust an internal pressure of the process chamber 360 by adjusting exhaust force. In one example, the exhaust member may be provided as a pump.

The process chamber 360 is disposed on a side portion of the transfer chamber 340. A plurality of process chambers 360 is provided. For example, four process chambers 360-1, 360-2, 360-3, and 360-4 may be provided, and may be paired or disposed on each side of the transfer chamber 340, respectively. The process chambers 360 may be provided to perform the same process with respect to the substrate W. Optionally, some of the process chambers 360 may be provided to sequentially perform a series of processes on the substrate W. Also, when a plurality of process chambers 360 is provided, each of the doors 364-1, 364-2, 364-3, and 364-4, and each of the exhaust members 368-1, 368-2, 368-3, and 368-4 may be independently driven by the controller 500.

Furthermore, each of the pressure sensors 346 and 366 is connected to the controller 500. The controller 500 is configured to receive and store the pressure values measured and transmitted by each of the pressure sensors 346 and 366. Furthermore, the controller 500 is provided to display the received values. According to an example, the controller 500 may be configured to graph the received pressure value and display the graph on a display device (not illustrated). In addition, the controller 500 may control the configuration of the substrate treating apparatus described above based on the result of analyzing the received value. According to an example, the controller 500 may be configured to stop the operation of each configuration based on the analysis result or to transmit the result to the operator through an alarm means which is not illustrated.

The controller 500 may include a Central Processing Unit (CPU), a Read Only Memory (ROM), and a Random Access 44-16 Memory (RAM). The CPU transfers the substrate according to various algorithms and recipes stored in the memory areas thereof, and executes desired treatment such as etching treatment. In the algorithm and the recipe, control information of the device regarding the order and condition of transferring the substrate and the process condition is input. Meanwhile, the algorithm and the recipe indicating these programs or process conditions may be stored in the non-transitory computer-readable medium. The non-transitory computer-readable medium refers to a medium that stores data semi-permanently and is readable by a computer, rather than a medium that stores data for a short moment, such as a register, cache, and memory. Specifically, the above-described various applications or programs may be stored and provided on a non-transitory readable medium, such as a CD, DVD, hard disk, Blu-ray disk, USB, memory card, or ROM.

Hereinafter, a method of treating a substrate will be described. The substrate treating method described below may be performed by the substrate treating apparatus described with reference to FIG. 1. Accordingly, hereinafter, the substrate treating method according to an exemplary embodiment will be described by referring to reference numerals denoted in FIG. 1. In addition, the substrate treating method described below may be performed by controlling the index module 100, the load lock chamber 200, and the treating module 300 by the controller 500.

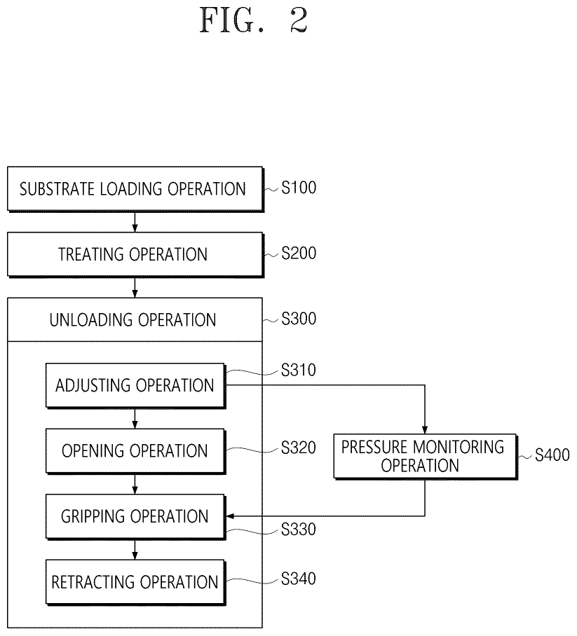

FIG. 2 is a flowchart illustrating a substrate treating method according to an exemplary embodiment of the present invention. Referring to FIG. 2, a substrate treating method according to an exemplary embodiment of the present invention includes a substrate loading operation S100, a treating operation S200, an unloading operation S300, and a pressure monitoring operation S400.

The substrate loading operation S100 is an operation of loading the substrate W from the transfer chamber 340 to the process chamber 360. The door 364 is opened, and the transfer robot 342 moves the handle 342a that grips the substrate W forward to the process chamber 360. The handle 342a transfers the substrate W to the process chamber 360 through the entrance 362. Thereafter, the substrate W is transferred to the substrate support unit provided in the process chamber 360, the handle 342a is retracted to the transfer chamber 340, and the door 364 is closed.

After the substrate loading operation S100, the treating operation S200 is performed. In the treating operation S200, the substrate W may be treated by plasma. For example, a process of etching a thin film on the substrate W or a process of etching an outermost edge region (bevel) of the substrate W may be performed. Impurities are formed during the process of treating the substrate W. When the substrate W is contaminated by the impurities, the substrate W may be discarded, and thus the impurities should be appropriately controlled.

After the treating operation S200, the unloading operation S300 is performed. After the treatment is completed, the substrate W is unloaded from the process chamber 360. The unloading operation S300 may include an adjusting operation S310, an opening operation S320, a gripping operation S330, and a retracting operation S340.

The adjustment operation S310 is an operation of adjusting the internal pressure of the process chamber 360 before opening the door 364 after the process is completed. In general, since the process of performing the process using plasma is performed at a pressure significantly lower than the internal pressure of the transfer chamber, when the door 364 is opened without adjusting the pressure, there is a risk that a strong airflow flows into the process chamber 360 and the remaining impurities fall onto the substrate W. To prevent such a problem, accordingly, in the adjusting operation S310, the pressure inside the process chamber 360 is adjusted to a pressure higher than the pressure when the process is in progress. For example, in the adjusting operation S310, the inside of the transfer chamber 340 may be maintained at a first pressure P1, the pressure inside the process chamber 360 may be adjusted to a second pressure P2, and the first pressure P1 may be a pressure higher than the second pressure P2.

After the adjusting operation S310, an opening operation S320 is performed. The opening operation S320 is an operation of opening the door 364. By opening the door 364, the internal spaces of the transfer chamber 340 and the process chamber 360 communicate with each other through the entrance 362.

After the opening operation S320, a gripping operation S330 is performed. In the gripping operation S330, the hand 342a of the transfer robot enters the process chamber 360 through the entrance 362. The hand 342a grips the substrate W supported by the support unit.

After the gripping operation S330, the hand 342a retracts. Accordingly, the substrate W is unloaded from the process chamber 360. The unloaded substrate W is transferred to FOUP or a chamber performing the next process for the next process. When there is a subsequent substrate W, the above process may be repeated from the loading operation S100.

The pressure monitoring operation S400 is an operation of monitoring the pressure inside the transfer chamber 300. The pressure monitoring operation S400 may be simultaneously performed in parallel while the process is performed from the substrate loading operation S100 to the unloading operation S300. According to an example, the pressure monitoring operation S400 may be performed from the adjusting operation S310 to the gripping operation S330.

The pressure monitoring operation S400 includes determining whether there is a pressure abnormality inside the transfer chamber 300. In the pressure monitoring operation S400, a graph representing the change in pressure in the transfer chamber 340 over time is acquired in real time, and it is possible to determine whether there is a pressure abnormality inside the transfer chamber 340 based on the shape of the graph. According to an example, when the shape of the graph is convex downward, the pressure inside the transfer chamber 340 is determined to be in a normal state, and when the shape of the graph is convex upward, the pressure inside the transfer chamber is determined to be in an abnormal state. Also, the graph of the internal pressure change of the process chamber 360 may be selectively acquired in the pressure monitoring operation S400. Hereinafter, the graph representing the pressure change of the transfer chamber 340 may be a first graph, and the graph representing the pressure change of the process chamber 360 may be a second graph. The value indicated by the second graph may also be used in the pressure monitoring operation S400 to determine whether the pressure inside the transfer chamber 340 is abnormal.

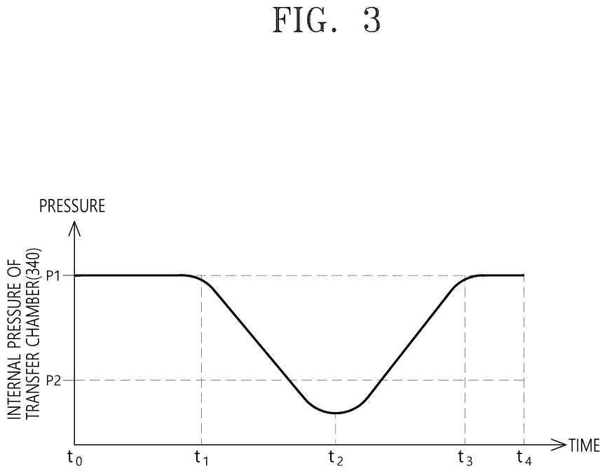

FIG. 3 is a diagram illustrating an example of a graph acquired in the pressure monitoring operation according to the exemplary embodiment of the present invention. Referring to FIG. 3, in the adjusting operation S100, the internal pressure of the transfer chamber 340 is formed at the first pressure P1 and is maintained at the first pressure P1 until the door 364 is opened (t₀ to t₁). Thereafter, in the opening operation S200, the door 364 is opened (t₁). When the door 364 is opened, the internal pressure of the transfer chamber 340 is formed higher than the internal pressure of the process chamber 360, and the internal space of the transfer chamber 340 is connected to the internal space of the process chamber 360 to instantaneously increase the volume of the entire space, so the pressure inside the transfer chamber 340 is reduced (t₁ to t₂). However, over time, the gas inside the transfer chamber 340 and the process chamber 360 diffuse to each other, and the above effects disappear as the transfer chamber 340 is exhausted at a constant exhaust pressure, and the pressure inside the transfer chamber 340 is restored to the first pressure P1 (t₂ to t₃). Thereafter, the transfer robot 342 grips the substrate W (t₄). A graph of the change in the internal pressure of the transfer chamber 340 through the above-described process has a convex downward shape. Similarly, the internal pressure of the process chamber 360 is also reduced at the second pressure P2 and recovered according to the above reasons. Accordingly, even when the opening operation S310 and the subsequent operation are performed, the internal pressure of the transfer chamber 340 may be maintained higher than the internal pressure of the process chamber 360 to prevent the inflow of the impurities into the transfer chamber 340.

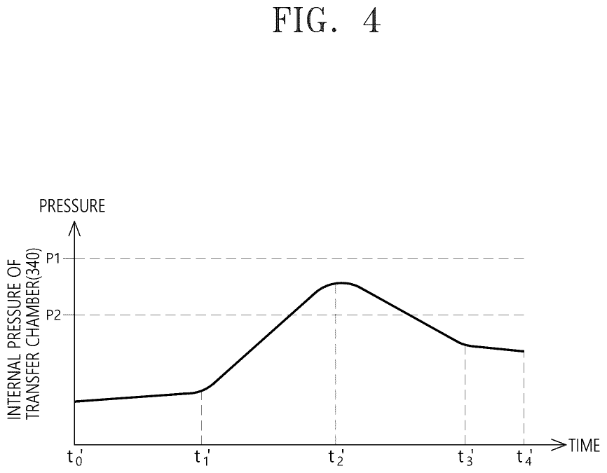

FIG. 4 is a diagram illustrating another example of a graph acquired in the pressure monitoring operation according to the exemplary embodiment of the present invention. When the opening operation S310 is performed in the plurality of process chambers 360-1, 360-2, 360-3, and 360-4 with a time difference, the transfer chamber 340 may undergo a pressure change as illustrated in FIG. 4. When the door 364-1 is opened to load or unload the substrate W, the internal pressure of the transfer chamber 340 is reduced as described above. The reduced internal pressure of the transfer chamber 340 may be in a state lower than the second pressure P2. Thereafter, the internal pressure of the transfer chamber 340 is recovered as time passes. However, when the at least one door 364-2, 364-3, and 364-4 is opened before the reduced pressure is recovered (t₁′), the internal pressure of the transfer chamber 340 may be in a state in which a pressure lower than the internal pressure of the process chamber 360 is formed. Accordingly, an airflow flowing from the process chamber 360 to the transfer chamber 340 may be formed. The pressure of the transfer chamber 340 is increased by the airflow (t₁′˜t₂′). The increased pressure is stabilized as time passes. The stabilized pressure may be a pressure lower than the first pressure P1. This is because exhaust force may affect the two process chambers 360-1 and 360-2 in order to be maintained at the second pressure P2 in a state in which the inside of the transfer chamber 340 and the two process chambers 360-1 and 360-2 communicate with each other. Accordingly, the pressure in the transfer chamber 340 over time has a convex shape upward in the graph.

As described above, while a plurality of doors 360-1, 360-2, 360-3, and 360-4 are opened with a time difference, the internal pressure of the transfer chamber 340 may be lower than the internal pressure of the process chamber 360. In this case, impurities in the process chamber 360 may diffuse into the transfer chamber 340, causing contamination of the transfer chamber 340.

According to the exemplary embodiment of the present invention, by detecting a change in the pressure of the transfer chamber 340 in real time in the pressure monitoring operation S400, it is possible to determine whether there is an abnormality in the internal pressure of the transfer chamber 340. When it is determined that the internal pressure of the transfer chamber 340 is in an abnormal state, the operator may clean the inside of the transfer chamber 340 to prevent the subsequent substrate W from proceeding. Accordingly, it is possible to prevent the subsequent substrate W from being contaminated in the transfer chamber 340.

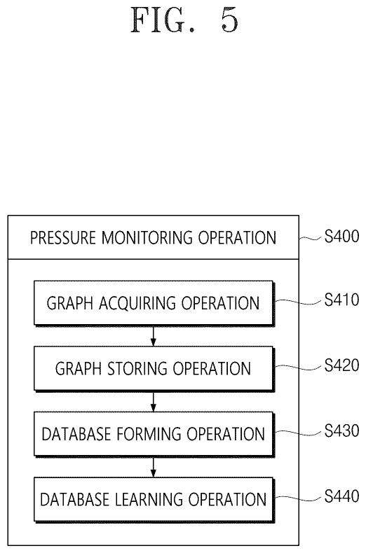

FIG. 5 is a flowchart illustrating the pressure monitoring operation according to another exemplary embodiment of the present invention. Referring to FIG. 5, the pressure monitoring operation S400 may further include a graph acquiring operation S410, a graph storing operation S420, a database forming operation S430, and a database learning operation S440.

The graph acquiring operation S410 is an operation of acquiring a graph representing a state in which the internal pressure of the transfer chamber 340 changes over time. The graph may be an upwardly convex graph or a downwardly convex graph. In the graph acquiring operation S410, a plurality of graphs may be acquired as the process of treating the substrate W is performed multiple times.

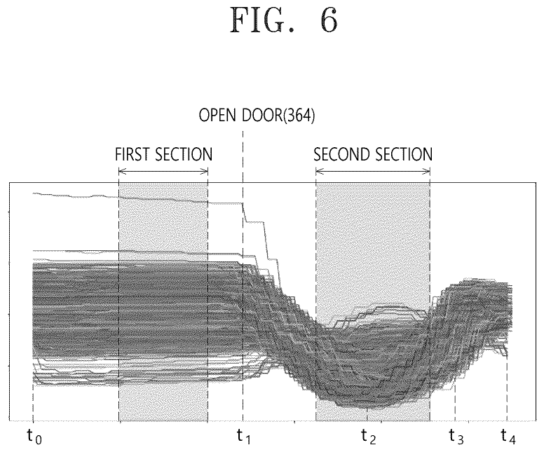

The graph acquiring operation S420 is an operation of storing the plurality of graphs acquired in the graph acquiring operation S410. FIG. 6 is a diagram illustrating an example of a state in which a plurality of graphs is acquired and stored. Referring to FIG. 6, a plurality of graphs may be divided into a group consisting of an upwardly convex graph and a group consisting of a downwardly convex graph. And it may be seen that within each group, the upwardly convex graph and the downwardly convex graph are spread. This is because the pressure of the transfer chamber 340 may be formed to a value within a certain range due to the influence of the position of the process chamber 360, the temporary performance change of the exhaust member 348, the operation of the transfer robot 342, the temporary malfunction of the pressure sensor 346, and the like in the process of transferring and treating the substrate W. This pressure spread may affect the shape of the graph, making it difficult to determine whether there is an abnormality in the pressure inside the transfer chamber 340.

The database forming operation S430 is an operation of converting the plurality of graphs acquired in the graph acquiring operation S420 into a database. The database may include an initial pressure value inside the transfer chamber in the loading operation S300, an average value of the pressure inside the transfer chamber 340 in a first section, an average value of the pressure inside the transfer chamber 340 in a second section, an average value of the pressure inside the process chamber 360 in the first section, and an average value of the pressure inside the process chamber 360 in the second section. The first section may be a set time interval before the door is opened in the unloading operation, and the second section may be a set time interval after the door is opened in the unloading operation. The first section may be a section included in the adjusting operation S320 so that the internal pressure of the transfer chamber 340 is constantly maintained, and the second section may be a section including a time during which the graph has a maximum value or a minimum value.

The database learning operation S440 is an operation of learning the database using an artificial intelligence learning model. The artificial intelligence may include a machine learning model, through which it is possible to more precisely detect the presence or absence of a pressure abnormality inside the transfer chamber 340 by analyzing vast amounts of data and learning patterns. In particular, when a machine learning model is used, it is very effective in analyzing data in the form of a graph, such as an internal pressure change of the transfer chamber 340. The pressure fluctuation over time is visualized in the form of a graph, and the machine learning model learns the graph so that it is possible to more precisely detect the presence or absence of a pressure abnormality inside the transfer chamber 340.

Various algorithms may be used as the machine learning model, and for example, a random forest model may be used. The Random Forest model is an ensemble learning technique based on decision trees. Random Forest builds several decision trees that have learned different samples and characteristics in the database, and synthesizes predictions of each tree to make a final decision. This method can effectively prevent overfitting problems that may occur in a single decision tree and provides robustness to handle various data patterns. Therefore, when the Random Forest model is used, abnormal patterns may be detected more accurately in various data samples, such as pressure changes in the transfer chamber, and precise analysis based on complex characteristics of data may be possible. According to another example, the machine learning model may include a Support Vector Machine (SVM), neural networks, and clustering techniques. However, the present invention is not limited thereto, and any machine learning model capable of detecting abnormal pressure is sufficient.

In the above-described exemplary embodiment, the method is described based on a flowchart as a series of operations or blocks, but the present invention is not limited to the order of operations, and some operations may occur in a different order or simultaneously with other operations as described above. In addition, those skilled in the art will understand that the operations illustrated in the flowchart are not exclusive and that other operations may be included or one or more operations in the flowchart may be deleted without affecting the scope of the present invention.

In the above example, the present invention has been described based on the case where the database includes the pressure value of the process chamber 360 as an example. However, the present invention is not limited thereto, and the pressure value of the process chamber 360 may not be included in the database. The machine learning model may be provided to learn only the pattern of the pressure value of the transfer chamber 340 to determine whether there is a pressure abnormality in the transfer chamber 340.

The foregoing detailed description illustrates the present invention. In addition, the above description shows and describes the exemplary embodiments of the present invention, and the present invention may be used in various other combinations, modifications, and environments. That is, changes or modifications are possible within the scope of the concept of the invention disclosed herein, the scope equivalent to the written disclosure, and/or within the scope of skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. In addition, the appended claims should be construed to include other exemplary embodiments as well.

What is claimed is:

1. A method of treating a substrate, the method comprising:
a substrate loading operation of loading a substrate into a process chamber selected from a plurality of process chambers with a transfer robot placed in a transfer chamber in a substrate treating apparatus including the transfer chamber and the plurality of process chambers placed around the transfer chamber;
a treating operation of treating the substrate in the process chamber into which the substrate is loaded;
after the treating operation, an unloading operation of opening a door of the transfer chamber, and unloading the substrate from the process chamber by using the transfer robot; and
a pressure monitoring operation of monitoring a pressure change inside the transfer chamber,
wherein a pressure in the process chamber is provided at a pressure lower than a pressure in the transfer chamber in the unloading operation, and
the pressure monitoring operation includes monitoring whether there is a pressure abnormality inside the transfer chamber.

2. The method of claim 1, wherein the pressure monitoring operation includes monitoring the pressure change in the transfer chamber in the unloading operation.

3. The method of claim 2, wherein the transfer robot includes a handle that grips a substrate,
the unloading operation includes a gripping operation of gripping the substrate in the process chamber with the handle, and
the pressure monitoring operation includes monitoring the pressure change inside the transfer chamber until the gripping operation.

4. The method of claim 3, wherein the pressure monitoring operation includes acquiring a first graph representing the pressure change in the transfer chamber over time, and
determining whether there is a pressure abnormality inside the transfer chamber based on a shape of the first graph.

5. The method of claim 4, wherein when the shape of the first graph is convex downward, it is determined that the pressure inside the transfer chamber is in a normal state, and
when the shape of the first graph is convex upward, it is determined that the pressure inside the transfer chamber is in an abnormal state.

6. The method of claim 5, wherein when it is determined that the pressure inside the transfer chamber is in the abnormal state, an alarm is generated.

7. The method of claim 4, wherein the pressure monitoring operation includes comparing the acquired first graph with a database to determine whether there is a pressure abnormality inside the transfer chamber, and
the database includes:
a plurality of first graphs acquired while the pressure monitoring operation has been performed multiple times in the past; and
a second graph representing a pressure change inside the process chamber acquired while the pressure monitoring operation has been performed multiple times in the past.

8. The method of claim 7, wherein the database includes:
an initial pressure value inside the transfer chamber in the unloading operation;
an average value of an internal pressure of the transfer chamber in a first section;
an average value of the internal pressure of the transfer chamber in a second section;
an average value of an internal pressure of the process chamber in the first section;
an average value of an internal pressure of the process chamber in the second section;
the first section is a set time interval before the door is opened in the unloading operation, and
the second section is a set time interval after the door is opened in the unloading operation.

9. The method of claim 8, wherein the database is learned using an artificial intelligence learning model, and it is determined whether there is the pressure abnormality inside the transfer chamber from the measured pressure change inside the transfer chamber.

10. An apparatus for treating a substrate, the apparatus comprising:
a transfer chamber including a transfer robot that transfers a substrate;
a plurality of process chambers provided adjacent to the transfer chamber; and
a controller,
wherein the transfer chamber has a first pressure sensor that measures a pressure inside the transfer chamber,
each of the plurality of process chambers has an exhaust unit that exhausts an inside of the process chamber,
each of the process chambers is provided to have an open state and a closed state by opening and closing a door,
the open state is a state in which the door is opened so that the transfer chamber and the process chamber communicate with each other,
the closed state is a state in which the door is closed so that the transfer chamber and the process chamber are blocked from each other,
in the closed state, an internal pressure of the transfer chamber is provided to have a first pressure, and an internal pressure of the process chamber is provided to have a second pressure lower than the first pressure,
the controller controls the transfer chamber and the process chamber to perform:
a treating operation of treating the substrate in the process chamber in which the substrate is loaded;
an unloading operation of unloading the treated substrate from the process chamber using the transfer robot; and
a pressure monitoring operation of monitoring a pressure change inside the transfer chamber and determining whether there is a pressure abnormality inside the transfer chamber, and
a pressure in the process chamber is provided at a pressure lower than a pressure in the transfer chamber in the unloading operation, and
whether there is the pressure abnormality inside the transfer chamber is monitored in the pressure monitoring operation.

11. The apparatus of claim 10, wherein the pressure change measured by the first pressure sensor is a pressure change in the open state.

12. The apparatus of claim 11, wherein the pressure change measured by the first pressure sensor is a pressure change until at least one of the plurality of process chambers is switched from the closed state to the open state, and a handle of the transfer robot enters the process chamber and grips the substrate.

13. The apparatus of claim 12, wherein the controller generates and acquires a first graph representing the pressure measured by the first pressure sensor in the monitoring operation as a change over time, and
determines whether there is the pressure abnormality inside the transfer chamber based on a shape of the first graph.

14. The apparatus of claim 13, wherein when the shape of the first graph is convex downward, the controller determines that the pressure inside the transfer chamber is in a normal state, and
when the shape of the first graph is convex upward, the controller determines that the pressure inside the transfer chamber is in an abnormal state.

15. The apparatus of claim 14, wherein the controller controls the transfer chamber or the process chamber to generate an alarm when it is determined that the pressure inside the transfer chamber is in the abnormal state.

16. The apparatus of claim 15, wherein each of the process chambers has a second pressure sensor that measures a pressure inside the process chamber,
the controller compares the acquired first graph with a database to determine whether there is the pressure abnormality inside the transfer chamber,
the database includes:
a plurality of first graphs acquired while the pressure monitoring operation has been performed multiple times in the past; and
a second graph representing a pressure change inside the process chamber acquired while the pressure monitoring operation has been performed multiple times in the past.

17. The apparatus of claim 16, wherein the database includes:
an initial pressure value inside the transfer chamber in the unloading operation;
an average value of the internal pressure of the transfer chamber in a first section;
an average value of the internal pressure of the transfer chamber in a second section;
an average value of an internal pressure of the process chamber in the first section;
an average value of an internal pressure of the process chamber in the second section;
the first section is a set time interval before the door is opened in the unloading operation, and
the second section is a set time interval after the door is opened in the unloading operation.

18. The apparatus of claim 17, wherein the controller learns the database using an artificial intelligence learning model, and monitors whether there is the pressure abnormality inside the transfer chamber from the measured first graph.

19. A method of treating a substrate, the method comprising:
a substrate loading operation of loading a substrate into a process chamber selected from a plurality of process chambers with a transfer robot placed in a transfer chamber in a substrate treating apparatus including the transfer chamber and the plurality of process chambers placed around the transfer chamber;
a treating operation of treating the substrate in the process chamber into which the substrate is loaded;
after the treating operation, an unloading operation of opening a door of the transfer chamber, and unloading the substrate from the process chamber by using the transfer robot; and
a pressure monitoring operation of monitoring a pressure change inside the transfer chamber and determining whether there is a pressure abnormality inside the transfer chamber,
a pressure in the process chamber is provided at a pressure lower than a pressure in the transfer chamber in the unloading operation, and
the transfer robot includes a handle that grips a substrate,
the pressure monitoring operation includes:
acquiring a first graph representing the pressure change in the transfer chamber over time in the unloading operation, and
determining whether there is the pressure abnormality inside the transfer chamber based on a shape of the first graph, and
when the shape of the first graph is convex downward, it is determined that the pressure inside the transfer chamber is in a normal state, and
when the shape of the first graph is convex upward, it is determined that the pressure inside the transfer chamber is in an abnormal state, and
when it is determined that the pressure inside the transfer chamber is in the abnormal state, an alarm is generated.

20. The method of claim 19, wherein the pressure monitoring operation includes learning a database using an artificial intelligence learning model, and determining whether there is the pressure abnormality inside the transfer chamber by comparing the acquired first graph and the database, and
the database includes:
an initial pressure value inside the transfer chamber in the unloading operation;
an average value of the internal pressure of the transfer chamber in a first section;
an average value of the internal pressure of the transfer chamber in a second section;
an average value of an internal pressure of the process chamber in the first section;
an average value of an internal pressure of the process chamber in the second section;
the first section is a set time interval before the door is opened in the unloading operation, and
the second section is a set time interval after the door is opened in the unloading operation.
